(19) United States
(12) Patent Application Publication
(10) Pub. No.: US 2002/0136985 A1
(43) Pub. Date: Sep. 26, 2002

(54) Heat sensitive printing plate precursors

(75) Inventor: John Michael Kitteridge, Leeds (GB)

Correspondence Address: LEYDIG VOIT & MAYER, LTD, TWO PRUDENTIAL PLAZA, SUITE 4900, 180 NORTH STETSON AVENUE, CHICAGO, IL, 60601-6780, US

(73) Assignee: Agfa-Gevaert, Mortsel (BE)

(21) Appl. No.: 10/047,580

(22) Filed: Jan. 15, 2002

Related U.S. Application Data
(60) Provisional application No. 60/270,439, filed on Feb. 21, 2001.

(30) Foreign Application Priority Data
Jan. 23, 2001 (EP) 01200230.9
Jan. 24, 2001 (EP) 01000002.4

(51) Int. Cl. G03F 7/004; G03F 7/06; G03F 7/11; G03F 7/36; G03F 7/40

(52) U.S. Cl. 430/276.1; 430/278.1; 430/273.1; 430/302; 430/309; 430/616

(57) ABSTRACT

A lithographic printing plate precursor comprises a grained and anodized aluminum substrate coated with a metallic layer, preferably a silver layer, on top of which is applied a layer comprising at least one oleophilising agent and at least one hydrophilic stain-reducing agent, the hydrophilic agent being chosen such that it adsorbs onto the metallic layer but is not so strongly adsorbed thereon as to displace the oleophilising agent. Preferably, the oleophilising agent comprises a mercaptotetrazole or mercaptooxadiazole derivative, the hydrophilic stain-reducing agent comprises a material which includes at least one sulfur, selenium or tellurium containing group, and the layer additionally comprises an additional hydrophilic material. The invention provides lithographic printing plate precursors which may be image-wise exposed by means of a high intensity laser beam to provide press ready plates showing reduced stain in non-image areas, high image quality, good press properties and high durability on press without the requirement for the use of intermediate film and developer chemistry.

This invention relates to the formation of images directly from electronically composed digital sources and is particularly concerned with the formation of images on lithographic printing plate precursors. More particularly, the invention relates to lithographic printing plate precursors which incorporate an imaging layer comprising metallic silver, and a method of preparing lithographic printing plates which does not require the use of chemical treatments.

Lithographic printing is a process of printing from surfaces which have been prepared in such a way that certain areas are capable of accepting ink (oleophilic areas), whereas other areas will not accept ink (oleophobic areas). The oleophilic areas form the printing areas while the oleophobic areas form the background areas.

Plates for use in lithographic printing processes may be prepared using a photographic material that is made image-wise receptive or repellent to ink upon photo-exposure of the photographic material and subsequent chemical treatment. However, this method of preparation, which is based on photographic processing techniques, involves several steps, and therefore requires a considerable amount of time, effort and expense.

Consequently it has, for many years, been a long-term aim in the printing industry to form images directly from an electronically composed digital database, i.e. by a so-called “computer-to-plate” system. The advantages of such a system over the traditional methods of making printing plates are:

(i) the elimination of costly intermediate silver film and processing chemicals;

(ii) a saving of time; and

(iii) the ability to automate the system with consequent reduction in labor costs.

The introduction of laser technology provided the first opportunity to form an image directly on a printing plate precursor by scanning a laser beam across the surface of the precursor and modulating the beam so as to effectively turn it on and off: In this way, radiation sensitive plates comprising a high sensitivity polymer coating have been exposed to laser beams produced by water cooled UV argon-ion lasers and electrophotographic plates having sensitivities stretching into the visible spectral region have been successfully exposed using low powered air-cooled argon-ion. helium-neon and semiconductor laser devices.

Imaging systems are also available which involve a sandwich structure that. on exposure to a heat generating infrared laser beam, undergoes selective (image-wise) delamination and subsequent transfer of materials. Such so-called peel-apart systems are generally used as replacements for silver halide films.

A digital imaging technique has been described in U.S. Pat. No 4,911,075 whereby a so-called driographic plate which does not require dampening with an aqueous fountain solution to wet the non-image areas during printing is produced by means of a spark discharge. In this case, a plate precursor comprising an ink-repellent coating containing electrically conductive particles coated on a conductive substrate Is used and the coating is ablatively removed from the substrate. Unfortunately, however, the ablative spark discharge provides images having relatively poor resolution.

It is known to improve this feature by the use of lasers to obtain high resolution ablation as described, for example, by P E Dyer in “Laser Ablation of Polymers” (Chapter 14 of “Photochemical Processing of Electronic Materials”, Academic Press, 1992, p359-385). Until recently, imaging via this method generally involved the use of high power carbon dioxide or excimer lasers. Unfortunately, such lasers are lot well suited to printing applications because of their high power consumption and excessive cost, and the requirement for high-pressure gas handling systems. Recent developments have, however, led to the availability of more suitable infrared diode lasers, which are compact, highly efficient and very economical solid state devices. High power versions of such lasers, which are capable of delivering up to 3000 mJ/cm², are now commercially available.

Coatings that may be imaged by means of ablation with infrared radiation have previously been proposed. Thus, for example, a proofing film in which an image is formed by image-wise ablation of a colored layer on to a receiver sheet is described in PCT Application No 90/12342. This system is, however, disadvantageous in requiring a physical transfer of material in the imaging step, and such methods tend to give rise to inferior image resolution.

Much superior resolution is obtained by means of the ablation technique described in European Patent No 649374, wherein a driographic printing plate precursor is imaged digitally by means of an infra-red diode laser or a YAG laser, and the image is formed directly through the elimination of unwanted material. The technique involves exposing a plate precursor, incorporating an infra-red radiation ablatable coating covered with a transparent cover sheet, by directing the beam from an infrared laser at sequential areas of the coating so that the coating ablates and loses its ink repellency in those areas to form an image, removing the cover sheet and ablation products, and inking the image.

A heat mode recording material is disclosed in U.S. Pat. No 4,034,183 that comprises an anodized aluminum support coated with a hydrophilic layer. On image-wise exposure using a laser, the exposed areas are rendered hydrophobic, and thereby accept ink.

Japanese patent application laid open to public inspection No 49-117102 (1974) discloses a method for producing printing plates wherein a metal is incorporated in the imaging layer of a printing plate precursor which is imaged by irradiation with a laser beam modulated by electric signals. Typically, the plate precursor comprises a metal base, such as aluminum, coated with a resin film, which is typically nitrocellulose, and on top of which has been provided a thin layer of copper. The resin and metal layers are removed in the laser-struck areas, thereby producing a printing plate. The disadvantage of this system, however, is that two types of laser beam irradiation are required in order to remove firstly the copper (e.g. by means of an argon-ion laser) and then the resin (e.g. with a carbon dioxide laser); hence, the necessary equipment is expensive.

Subsequently a method of printing plate production which obviated the requirement for a second laser exposure was disclosed in Japanese patent application laid open to public inspection No 52-37104 (1977). Thus, a printing plate precursor comprising a support, typically aluminum, an anodic aluminum oxide layer, and a layer of brass, silver, graphite or, preferably, copper is exposed to a laser beam of high energy density in order to render the exposed areas hydrophilic to yield a printing plate. The printing plate precursor is, however, of rather low sensitivity and requires the use of a high-energy laser for exposure.

An alternative heat mode recording material for making a lithographic printing plate is disclosed in European Patent No 609941, which comprises a support having, a hydrophilic surface, or provided with a hydrophilic layer, on which is coated a metallic layer, on top of which is I hydrophobic layer having a thickness of less than 50 nm. A lithographic printing plate may be produced from the said material by image-wise exposing to actinic radiation, thereby rendering the exposed areas hydrophilic and repellent to greasy ink.

Conversely, European Patent No 628409 discloses a heat mode recording material for making a lithographic printing plate which comprises a support and a metallic layer, on top of which is provided a hydrophilic layer having a thickness of less than 50 num. A lithographic printing plate is produced by image-wise exposing the material to actinic radiation in order to render the exposed areas hydrophobic and receptive to greasy ink.

In each of the two foregoing heat mode recording materials, however, difficulties in printing will be encountered. On exposure of the materials to actinic radiation, the energy is converted to heat in the image areas by interaction with the metallic layer, thereby destroying the hydrophilicity or hydrophobicity—depending on the material employed—of the topmost layer in those areas. Consequently, the surface of the metallic layer becomes exposed, and the success of the printing operation is dependent upon differences in hydrophilicity and oleophilicity between the metallic surface and the hydrophilic or hydrophobic layer, as the case may be. Since the metallic layer functions as the hydrophobic surface in one case, and as the hydrophilic surface in the alternative case, it would be expected that such differences in hydrophilicity and oleophilicity would not be sufficiently clearly defined so as to provide a satisfactory printing surface. Furthermore, when a hydrophilic layer is present, and the metallic surface functions as the oleophilic areas of the plate, image areas will necessarily be printed from the metallic surface; such an arrangement is known to be unsatisfactory, and to result in difficulties in achieving acceptable printing quality.

Subsequently, a series of PCT patent applications (WO 98/55307-WO 98/55311 and WO 98/55330-WO 98/55332) has disclosed heat mode recording materials comprising a grained and anodized aluminum substrate and an ablatable metallic layer, said materials providing lithographic printing plates showing high image quality and excellent printing properties. Also described are imaging methods for the preparation of the said printing plates, these methods relying on direct-to-plate exposure techniques and thereby obviating the requirement for the use of costly intermediate film or processing developers after exposure.

Individual specifications within this series of patent applications also disclose various distinct additional features such as the inclusion of an further layer on top of the metallic layer; for example, WO 98155311 teaches the presence of a transparent cover sheet or layer of material to collect ablated debris, whereas WO98/55308 describes a hydrophobizing layer comprising a proteolytic enzyme and an oleophilizing agent, this layer improving the ink-accepting properties of image areas and thereby increasing the degree of differentiation between hydrophilic and oleophilic areas.

Lithographic printing plate precursors of this type do, however, suffer from the disadvantage that ablation can be incomplete in the exposed areas. This is evidenced by the presence of a stain caused by redeposited or incompletely removed material. This stain can cause printing problems in the exposed non-image areas. In addition, the presence of a stain is cosmetically undesirable. The present invention, therefore, seeks to reduce or eliminate this stain and to improve the printing properties of the exposed areas of the plate.

Surprisingly it has now been found that the incorporation of a hydrophilic material that adsorbs onto the metallic layer reduces the level of staining and the amount of ablatable material remaining in the exposed areas, and thereby diminishes any tendency for the ablated areas to take ink.

Thus, according to a first aspect of the present invention there is provided a lithographic printing plate precursor comprising:

(a) a grained and anodized aluminum substrate, having provided thereon

(b) a metallic layer, on top of which is applied

(c) a layer comprising

(i) at least one oleophilising agent which is adsorbed onto the metallic layer; and

(ii) at least one hydrophilic stain-reducing agent,

said hydrophilic agent being adsorbable onto the metallic layer without displacing the adsorbed oleophilising agent.

The substrate employed in the present invention is an aluminum substrate that has been electrochemically grained and anodized on at least one surface in order to enhance its lithographic properties. Optionally, the aluminum may be laminated to other materials, such as paper or various plastics materials, in order to enhance its flexibility, whilst retaining the good dimensional stability associated with aluminum.

The metallic layer, which is applied to the grained and anodized surface of the aluminum, may comprise one or a combination of several metals, specific examples of which include copper, bismuth and brass. Most preferably, however, the metallic layer comprises a silver layer. The thickness of the metallic layer is preferably from 1 nm to 100 nm, most preferably from 10 nm to 50 nm.

Various techniques are available for the application of the metallic layer to the grained and anodized aluminum substrate, including vapor or vacuum deposition or sputtering. In the case where the metal layer comprises a silver layer, however, the most preferred method for applying the layer involves the treatment of a silver halide material according to the silver salt diffusion transfer process.

In the diffusion transfer process, a silver halide emulsion layer is transformed by treatment with a so-called silver halide solvent, into soluble silver complex compounds which are then allowed to diffuse into an image receiving layer and are reduced therein by means of a developing agent, generally in the presence of physical development nuclei, to form a metallic silver layer.

Two such systems are available: a two sheet system in which a silver halide emulsion layer is provided on one element, and a physical development nuclei layer is provided on a second element, the two elements are placed in contact in the presence of developing agent(s) and silver halide solvent(s) in the presence of an alkaline processing liquid, and subsequently peeled apart to provide a metallic silver layer on the second element; and a single sheet system wherein the element is provided with a physical development nuclei layer, a silver halide emulsion layer is provided oil top thereof, the element is treated with developing agent(s) and silver halide solvent(s) in the presence of an alkaline processing liquid, and the element is washed to remove spent emulsion layer and leave a metallic silver layer which is formed in the layer containing physical development nuclei.

Alternatively, the diffusion transfer process may be used to apply a metallic silver layer by overall exposing a positive working silver halide emulsion layer to form a latent negative image which is then developed in contact with a physical development nuclei layer to form a metallic silver layer. Again, the process may be carried out using either a single sheet or a double sheet system.

The principles of the silver complex diffusion transfer process are fully described in the publication “Photographic Silver Halide Diffusion Processes” by Andre Rott and Edith Weyde, The Focal Press, London and New York, 1972, and further detail may be gleaned by reference thereto.

The topmost layer thus comprises at least one oleophilising agent which adsorbs onto the metallic surface, and at least one hydrophilic stain-reducing agent which is also able to adsorb on the metallic surface. The hydrophilic agent should be less strongly adsorbing than the oleophilising agent and the relative quantities used should be such that the oleophilising agent is not desorbed from the metallic surface.

Specifically, where the metallic layer is a silver layer, the oleophilising agents are typically those disclosed on pages 105 to 106 of the publication “Photographic Silver Halide Diffusion Processes” by Andre Rott and Edith Weyde, The Focal Press, London and New York, 1972. Examples of suitable oleophilising agents include various mercaptan, mercapto and thio derivatives, such as dodecylmercaptan, octadecylmercaptan, 2-mercaptobenzothiazole, 2-mercaptobenzoxazole, 2-mercapto-5-methylbenzimidazole, 1-octyl-1,2,4,5-tetrahydro-s-triazine-5-thiol, 1,3-diphenyl-2-thiourea, 4-phenyl-3-thiosemicarbazide, dodecyl-3-mercaptopropionate, octyl thiosalicylate and 6-octyl-2-thiouracil. Preferred oleophilising agents are the mercaptotetrazoles and mercaptooxadiazoles, specifically 1-phenyl-5-mercaptotetrazole, sodium 1-octyl-5-mercaptotetrazole and n-heptyl-2-mercapto-1,3,4-oxadiazole. The oleophilising agent is applied to the metallic layer in an amount of from 0.1 to 10 mg/m², preferably from 1 to 5 mg/m².

Again, in those cases wherein the metallic layer comprises a silver layer, significant stain reductions in the ablated areas have resulted from the application of layers comprising hydrophilic agents which include at least one sulfur, selenium or tellurium containing group. In particular, suitable groups include thiol groups, substituted thio groups which are readily hydrolyzed to provide thiol groups, disulfide groups, thioacid groups, thioamide groups and thiocyanate groups, together with the selenium and tellurium analogues of the foregoing. Examples of hydrophilic stain-reducing agents for incorporation in the topmost layer include the following materials:

1. Thiosulphates, such as sodium thiosulphate or ammonium thiosulphate.

2. Thiocarboxylic acids, such as 2-mercaptosuccinic acid and its salts.

3. Thioalcohols, such as 2-mercapto-1,3-propanediol.

4. Thioamides, such as thiourea.

5. Thio containing amino acids, such as L-cysteine.

6. Thiosulphonic acids, such as 3-mercapto-1-propanesulphonic acid and its salts.

7. Thiocyanates, such as potassium thiocyanate.

Most preferably, the hydrophilic agent comprises sodium thiosulphate.

The hydrophilic stain reducing agent is preferably applied to the metallic layer in an amount of from 0.01 to 5 g/m², preferably from 0.01 to 0.5 g/m².

Preferably, the topmost layer also includes at least one additional hydrophilic material which, in addition to serving as a binder, can act as an ink desensitizer for the anodized aluminum surface revealed after image-wise ablation of the overlying metallic layer, ultimately rendering said aluminum surface more hydrophilic, and hence reducing unwanted take-up of ink in the background, non-image, areas.

Virtually any of the hydrophilic materials commonly used as desensitizing agents for background areas of lithographic printing plates during printing operations may be used for present purposes, but specific examples include sodium hexametaphosphate, sodium gluconate, dextrin, gum arabic and sorbitol.

During conventional platemaking operations, desensitizing agents of this type are generally applied to a plate surface following image-wise exposure and, when appropriate, development. However, the presence of said hydrophilic materials and the hydrophilic stain reducing agent prior to exposure obviates the requirement for such post-exposure treatments, and facilitates direct-to-press application of the printing plate.

Thus, the plate may be directly transferred to a printing press following exposure, without the requirement for any intermediate treatment, since the hydrophilic materials are readily removable from the silver image in printing areas by means of aqueous washing; such washing is effectively achieved by the action of the typical aqueous fount solutions and fount-ink mixtures commonly used on printing presses, and the hydrophilic material is thereby replaced by a film of ink in image areas and fount in background, non-image areas. An alternative means of direct to press exposure is also possible, wherein the plate precursor is exposed in situ on a printing press.

The present invention also effectively provides a method by which the printing characteristics of lithographic printing plate precursors comprising a substrate and a metallic layer may be further improved. Thus, according to a second aspect of the present invention, there is provided a method for reducing the background stain of a heat mode laser exposed lithographic printing plate precursor, the said method comprising:

(a) providing a lithographic printing plate precursor comprising a grained and anodized aluminum substrate having provided thereon a metallic layer; and

(b) applying, on the metallic layer, a layer comprising

(i) at least one oleophilising agent which is adsorbed onto the metallic layer; and

(ii) at least one hydrophilic stain-reducing agent,

said hydrophilic agent being adsorbable onto the metallic layer without displacing the adsorbed oleophilising agent.

The topmost layer may be applied from aqueous or organic solvent solution using any suitable coating technique selected from those well known in the art such as, for example, dip coating, gravure coating, spray coating, slot coating or reverse roll coating. The layer may solely comprise the oleophilising and hydrophilic stain reducing agents but, preferably, additionally includes further materials chosen from wetting agents, dispersing agents, biocides, buffers, dyes, or other materials which may enhance the press performance of the final printing plate, in addition to the hydrophilic materials previously discussed. Preferably, the hydrophilic stain reducing agent is present in the layer to the extent of between 10 and 90%.

The coating solution should preferably have a pH of between 3 and 10, since damage to the metallic layer may result from a coating solution having a pH that is either too high or too low. It is also advantageous to avoid the presence of oxidizing agents in the coating solution.

The hydrophilic stain reducing agent and oleophilising agent may be applied together with the other materials previously specified to give a total dry coating weight of between 0.01 and 10 g/m², preferably between 0.01 and 0.5 g/m². With the exception of the oleophilising agent, the components of the said layer should, after exposure, be readily removed from the surface of the metallic layer by simple aqueous washing( in order to facilitate rapid ink acceptance in image areas, thereby ensuring that the plate has good roll-up properties.

According to a third aspect of the present invention, there is provided a method of preparing a lithographic printing plate, said method comprising:

(a) providing a lithographic printing plate precursor as hereinbefore described; and

(b) image-wise exposing said precursor by means of a heat mode laser beam.

The lithographic printing plate precursor is imaged by a beam of radiation, preferably from a laser operating in the infrared region of the spectrum. Examples of suitable infrared lasers include semiconductor lasers and YAG lasers, for example the Gerber Crescent 42T Platesetter with a 10 W YAG laser outputting at 1064 nm. Exposure to the beam of radiation causes ablation of the metallic layer to occur in the radiation-struck areas. Additionally, the metallic layer may be exposed to lasers providing radiation of other wavelengths, such that a heating effect—which leads to ablation—is produced. A suitable example is a KrF laser outputting at 248 nm and generating power density of 3 MW/cm².

Said exposure may be carried out with the printing plate precursor mounted on a printing press or, in the alternative, using a separate exposure station. In the latter case, following image-wise exposure, the resulting plate may have directly mounted on a printing press; in either event, removal of the top layer, together with any silver particles remaining in exposed areas, occurs either as a result of the action of the press fount solutions, or other start-up chemicals, on the plate surface, or during the course of other procedures involved in the printing operation.

Alternatively, after exposure, the plate may be subjected to a manual or automatic scrubbing and/or soaking treatment with an aqueous solution in order to remove the top layer; this procedure, which is described in PCT patent application no. WO 98/55309, additionally facilitates removal of any silver particles remaining in exposed areas, and enables the cosmetic appearance of the plate to be improved prior to press operations.

The present invention provides lithographic printing plate precursors which may be used according to the method of the third aspect of the present invention to provide press ready plates showing high image quality, good press properties and high durability on press without the requirement for the use of costly intermediate film and developer chemistry and the attendant inconvenience resulting from the use of these materials.

The following example is illustrative of the invention, without placing any limit on the scope thereof:

### EXAMPLE

Samples of a commercially available Howson SILVERLITH® SDB printing plate, available from Agfa-Gevaert Ltd., were processed without exposure through all automatic processor by means of the diffusion transfer reversal method, in accordance with the recommendation of the manufacturer, but a bacterial protease enzyme was added to the water washing stage, and the final stage of applying a specified finishing gum was omitted. The resulting samples of printing plate precursor comprised a grained and anodized aluminum substrate, on the anodized surface of which was a coated layer of silver at a coat weight of 0.5 g/m².

A sample of the plate precursor was roller coated with Solution A, then dried at 60° C., to give a dry topcoat weight of 0.5 g/m².

| Solution A | | |
|---|---|---|
| Sodium 1-octyl-5-mercaptotetrazole | 1.5 | g |
| Tris(hydroxymethyl)aminomethane | 15 | g |
| Sodium 2-ethylhexylsulphate (40%) | 75 | ml |
| Sodium octanoate (40%) | 265 | ml |
| Sodium hexametaphosphate | 75 | g |
| Potassium citrate | 75 | g |
| Sorbitol | 50 | g |
| Stain reducing agent | 0.2 | molar |

| | |
|---|---|
| | (see Table 1) |
| Sodium hydroxide | to pH 9 |
| Water | to 1 liter |

TABLE 1

| Test | | Amount, |
|---|---|---|
| number | Hydrophilic stain-reducing agent | g/l |
| 1 | None | — |
| 2 | Potassium thiocyanate, KSCN | 19.4 |
| 3 | L-Cysteine, | 24 |
| | HS—CH₂—CH(NH₂)—COOH | |
| 4 | L-Cystine, | 24 |
| | (—S—CH₂—CH(NH₂)—COOH)₂ | (0.1 molar) |
| 5 | Thiosalicylic acid, | 30.8 |
| | HS—C₆H₄—COOH | |
| 6 | Sodium thiosulphate, | 50 |
| | NaS₂O₃.5H₂O | |
| 7 | 2-Mercaptosuccinic acid, | 30 |
| | HS—CH(COOH)—CH₂—COOH | |

The samples were then loaded onto a Gerber Crescent 42T internal drum Laser Platesetter and image-wise exposed to a 10 W YAG laser outputting at a wavelength of 1064 nm. The maximum available exposure on the Gerber 42T Platesetter. 255 units, was used. The stain in the exposed areas was measured on a Minolta CR231 colorimeter, and the results of the evaluation were as detailed in Table 2.

TABLE 2

| Test number | L* | a* | b* |
|---|---|---|---|
| 1 (control) | 66.85 | 2.61 | 13.23 |
| 2 | 69.41 | 1.51 | 15.28 |
| 3 | 70.89 | 1.56 | 5.38 |
| 4 | 68.63 | 2.72 | 9.51 |
| 5 | 68.26 | 3.23 | 7.96 |
| 6 | 68.58 | 2.26 | 6.05 |
| 7 | 70.98 | 1.73 | 6.71 |

The L* value gives the lightness, 0 is black, 100 white.
a* gives the red-green color, −100 is green, +100 red.
b* gives the yellow-blue color, −100 is blue, +100 yellow.

The best cosmetic appearance is with L* as high as possible and a* and b* close to zero.

The above exposed samples were washed with water to remove any loose silver and other ablation debris. The silver remaining in the exposed ablated areas was measured on a calibrated Asoma XRF counter. The results are shown in Table 3.

TABLE 3

| Test number | Remaining silver, g/m² |
|---|---|
| 1 (control) | 0.073 |
| 2 | 0.065 |
| 3 | 0.064 |
| 4 | 0.079 |
| 5 | 0.055 |
| 6 | 0.055 |
| 7 | 0.068 |

1. A lithographic printing plate precursor comprising:
(a) a grained and anodized aluminum substrate, having provided thereon
(b) a metallic layer, on top of which is applied
(c) a layer comprising
(i) at least one oleophilising agent which is adsorbed onto the metallic layer; and
(ii) at least one hydrophilic stain-reducing agent.
said hydrophilic agent being adsorbable onto the metallic layer without displacing the adsorbed oleophilising agent.

2. A lithographic printing plate precursor as claimed in claim 1 wherein said metallic layer comprises a silver layer.

3. A lithographic printing plate precursor as claimed in claim 1 Wherein S lid metallic layer has a thickness of from 1 nm to 100 nm.

4. A lithographic printing plate precursor as claimed in claim 1 wherein said oleophilising agent comprises a mercapto, mercaptan or thio derivative.

5. A lithographic printing plate precursor as claimed in claim 1 wherein said oleophilising agent comprises a mercaptotetrazole or mercaptooxadiazole derivative.

6. A lithographic printing plate precursor as claimed in claim 1 wherein said oleophilising agent is applied at a dry coating weight of between 0.1 and 10 mg/m².

7. A lithographic printing plate precursor as claimed in claim 1 wherein said hydrophilic stain-reducing agent comprises a material which includes at least one sulfur, selenium or tellurium containing group.

8. A lithographic printing plate precursor as claimed in claim 7 wherein said sulfur, selenium or tellurium containing group comprises a thiol, substituted thio, disulfide, thioacid, thioamide or thiocyanate group, or a selenium and tellurium analogue thereof.

9. A lithographic printing plate precursor as defined in any preceding claim wherein said hydrophilic stain-reducing agent is present in said layer to the extent of between 10 and 90%.

10. A lithographic printing plate precursor as claimed in any preceding claim wherein said layer containing at least one oleophilising agent and at least one hydrophilic stain-reducing agent additionally comprises at least one additional hydrophilic material.

11. A lithographic printing plate precursor as claimed in claim 10 wherein said additional hydrophilic material comprises a compound capable of desensitizing the non-image areas of the exposed plate precursor to ink.

12. A lithographic printing plate precursor as claimed in claim 11 wherein said desensitizer comprises sodium hexametaphosphate, sodium gluconate, dextrin, gum arabic or sorbitol.

13. A lithographic printing plate precursor as claimed in any preceding claim wherein said layer containing at least one oleophilising agent and at least one hydrophilic stain-reducing agent has a dry coating weight of between 0.01 and 10 g/m².

14. A method for reducing the background stain of a heat mode laser exposed lithographic printing plate precursor, the said method comprising:
(a) providing a lithographic printing plate precursor comprising a grained and anodized aluminum substrate having provided thereon a metallic layer; and
(b) applying, on the metallic layer, a layer comprising
(i) at least one oleophilising agent which is adsorbed onto the metallic layer; and
(ii) at least one hydrophilic stain-reducing agent.
said hydrophilic agent being adsorbable onto the metallic layer without displacing the adsorbed oleophilising agent.

15. A method of preparing a lithographic printing plate, said method comprising:
(a) providing a lithographic printing plate precursor as claimed in any of claims 1 to 13; and
(b) image-wise exposing said precursor by means of a heat mode laser beam.

16. A method as claimed in claim 15 which additionally includes the step of subjecting the plate to a manual or automatic scrubbing and/or soaking treatment with an aqueous solution.
